(19) United States
(12) Patent Application Publication
(10) Pub. No.: US 2009/0117723 A1
(43) Pub. Date: May 7, 2009

(54) Methods of forming a conductive pattern in semiconductor devices and methods of manufacturing semiconductor devices having a conductive pattern

(75) Inventors: Jong-Kyu Kim, Yongin-si (KR); Bum-Soo Kim, Nam-gu (KR); Jong-Heui Song, Suwon-si (KR); Sang-Sup Jeong, Suwon-si (KR); Sung-Gil Choi, Yongin-si (KR); Kuk-Han Yoon, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Gyeonggi-do (KR)

(21) Appl. No.: 12/287,945

(22) Filed: Oct. 15, 2008

(30) Foreign Application Priority Data
Nov. 7, 2007 (KR) 10-2007-0113260

(51) Int. Cl. H01L 21/28; H01L 21/283

(52) U.S. Cl. 438/585; 438/669; 438/594; 257/E21.159; 257/E21.209; 257/E21.19

(57) ABSTRACT

In a method of forming a conductive pattern in a semiconductor device, a conductive layer including a metal is formed on a substrate. A mask including carbon is provided on the conductive layer, and the conductive pattern is formed on the substrate by etching the conductive layer using the mask as an etching mask. The mask is removed from the conductive pattern by an oxygen plasma ashing process. An oxidized portion of the conductive pattern is reduced. The conductive pattern may have a desired resistance by reducing the oxidized portion to improve electrical characteristics and reliability of the semiconductor device.

### FIELD

Example embodiments relate to methods of forming conductive patterns in semiconductor devices and methods of manufacturing semiconductor devices having a conductive pattern. For example, example embodiments relate to methods of forming conductive patterns having low resistance and methods of manufacturing semiconductor devices including the conductive patterns.

### BACKGROUND

As information process apparatuses have rapidly developed, demand has increased for a semiconductor device capable of providing high response speed and large storage capacity. However, the design rule of the semiconductor device can be decreased as the integration degree of the semiconductor device is increased. As a result, patterns in a semiconductor device can become fine, and adjacent patterns can have a minute interval. When the fine patterns of the semiconductor device the minute intervals, the critical dimensions (CD) of the patterns can be greatly reduced, whereas the resistances of the patterns can be greatly increased.

With regard to the resistance of a minute interval in a semiconductor device, the pattern or the wiring in some semiconductor devices can be generally formed using a metal instead of polysilicon doped with impurities.

In forming the pattern or the wiring including a metal, a metal film is formed on a substrate, and a mask is provided on the metal film. Then, the metal film is etched using the mask to form the pattern or the wiring including the metal on the substrate. The mask is removed from the pattern or the wiring including metal after forming the pattern or the wiring on the substrate. For example, the mask is usually removed by an oxygen (O₂) plasma etching process in which an oxygen gas is used as a source gas to generate an oxygen plasma for etching the mask.

In some methods, the mask is removed from the pattern or the wiring by a remote plasma ashing process. In the remote plasma ashing process, an oxygen plasma is generated in a plasma generator separated from a process chamber in which the remote plasma ashing process is carried out, and then oxygen ions are filtered from the oxygen plasma to selectively provide the process chamber with oxygen radicals in the oxygen plasma. The remote plasma ashing process may be performed at a temperature above about 200° C. to cause a chemical reaction between the mask and the oxygen radicals.

When the mask includes carbon, carbon atoms in the mask can react with the oxygen radicals, so the mask can be exhausted from the process chamber as gaseous byproducts including carbon monoxide (CO) or carbon dioxide (CO₂).

However, portions of the pattern or the wiring exposed by the mask may also react with the oxygen radicals while removing the mask from the pattern or the wiring including a metal. When the pattern or the wiring has an oxidized portion, the resistance of the pattern or the wiring may increase and deteriorate the electrical characteristics of the semiconductor device. For example, a semiconductor device with a high degree of integration and minute design rule can have considerably deteriorated reliability and electrical characteristics because the pattern or the wiring including the oxidized portion can have a great effect on the semiconductor device.

### SUMMARY

This application claims priority under 35 U.S.C. §119 to Korean Patent Application No. 2007-113260, filed on Nov. 7, 2007 in the Korean Intellectual Property Office (KIPO), the contents of which are herein incorporated by reference in their entirety.

Example embodiments provide a method of forming a conductive pattern in a semiconductor device that may provide a desired resistance to improve electrical characteristics and reliability of the semiconductor device.

Example embodiments provide a method of manufacturing a semiconductor device including a conductive pattern of a desired resistance to enhance electrical characteristics and reliability of the semiconductor device.

According to one aspect of example embodiments, there is provided a method of forming a conductive pattern in a semiconductor device. In the method of forming the conductive pattern in the semiconductor device, a conductive layer including a metal is formed on a substrate. A mask structure including carbon is formed on the conductive layer. The conductive pattern is formed on the substrate by etching the conductive layer using the mask structure as an etching mask. The mask structure is removed by a plasma ashing process using a source gas including oxygen. An oxidized portion of the conductive pattern formed in the plasma ashing process is reduced.

In the formation of the mask structure according to example embodiments, an amorphous carbon layer pattern may be formed on the conductive layer, and then a photoresist pattern may be formed on the amorphous carbon layer pattern.

In example embodiments, the mask structure may be removed at a temperature of about 5° C. to about 65° C., a flow rate of the source gas of about 100 sccm to about 500 sccm, and a pressure of about 10 mTorr to about 100 mTorr by applying a bias power of about 100 W to about 500 W.

In some example embodiments, the mask structure may be removed at a temperature of about 65° C. to about 250° C., a flow rate of the source gas of about 20 sccm to about 100 sccm, and a pressure of about 10 mTorr to about 300 mTorr by applying a bias power of about 20 W to about 100 W.

In example embodiments, the oxidized portion of the conductive pattern may be reduced using a reaction gas including hydrogen. For example, the reaction gas may include hydrogen (H₂) gas and/or ammonia (NH₃) gas.

In example embodiments, the plasma ashing process may be carried out using an induced couple plasma apparatus.

In example embodiments, removing the mask and reducing the oxidized portion of the conductive pattern may be performed in-situ.

In example embodiments, the metal in the conductive layer may include tungsten (W), aluminum (Al), cobalt (Co), copper (Cu), titanium (Ti), tantalum (Ta), etc. These metals may be used alone or in a mixture thereof.

In example embodiments, the conductive pattern may include a metal nitride. For example, the conductive pattern may include tungsten nitride, aluminum nitride, titanium nitride, tantalum nitride, etc. These materials may be used alone or in a mixture thereof.

According to another aspect of example embodiments, there is provided a method of manufacturing a semiconductor device. In the method of manufacturing the semiconductor device, a tunnel insulation layer is formed on a substrate. A preliminary floating gate is formed on the tunnel insulation layer. A dielectric layer is formed on the preliminary floating gate. A conductive layer including metal is formed on the dielectric layer. After a mask including carbon is formed on the conductive layer, a control gate, a dielectric layer pattern and a floating gate are formed by etching the conductive layer, the dielectric layer and the preliminary floating gate using the mask as an etching mask. The mask is removed from the control gate by an oxygen plasma ashing process. Then, an oxidized portion of the control gate formed in the oxygen plasma ashing process is reduced.

In the formation of the mask according to example embodiments, an amorphous carbon layer may be formed on the conductive layer, and a photoresist pattern may be formed on the amorphous carbon layer. Then, an amorphous carbon layer pattern may be formed on the conductive layer by etching the amorphous carbon layer using the photoresist pattern as an etching mask.

In example embodiments, the mask may be removed at a temperature of about 5° C. to about 250° C., a flow rate of a source gas of about 20 sccm to about 500 sccm, and a pressure of about 10 mTorr to about 300 mTorr by applying a bias power of about 10 W to about 500 W.

In example embodiments, the oxidized portion of the control gate may be reduced using a reaction gas including hydrogen. For example, the reaction gas may include hydrogen gas and/or ammonia gas.

According to still another aspect of example embodiments, there is provided a method of manufacturing a semiconductor device. In the method of manufacturing the semiconductor device, a gate insulation layer is formed on a substrate, and a conductive layer including metal is formed on the gate insulation layer. A mask including carbon is formed on the conductive layer. A gate electrode is formed on the gate insulation layer by etching the conductive layer using the mask as an etching mask. The mask is removed from the gate electrode by an oxygen plasma ashing process. An oxidized portion of the gate electrode formed in the oxygen plasma ashing process is reduced.

In the formation of the mask according to example embodiments, an amorphous carbon layer may be formed on the conductive layer. A photoresist pattern may be formed on the amorphous carbon layer. An amorphous carbon layer pattern may be formed on the conductive layer by etching the amorphous carbon layer using the photoresist pattern as an etching mask.

In example embodiments, the mask may be removed from the gate electrode at a temperature of about 5° C. to about 250° C., a flow rate of a source gas of about 20 sccm to about 500 sccm, and a pressure of about 10 mTorr to about 300 mTorr by applying a bias power of about 10 W to about 500 W.

In example embodiments, removing the mask and reducing the oxidized portion of the gate electrode may be performed in-situ.

In example embodiments, the oxidized portion of the gate electrode may be reduced using a reaction gas that includes hydrogen gas and/or ammonia gas.

According to example embodiments, the mask structure having an amorphous carbon layer pattern and a photoresist pattern may be effectively removed from the conductive pattern including metal by the plasma ashing process after forming the conductive pattern using the mask structure. When the plasma ashing process is performed at a relatively high temperature, the oxidized portion of the conductive pattern formed in the plasma ashing process may be reduced by a reduction process. Thus, the conductive pattern may have a desired resistance, so the semiconductor device including the conductive pattern may have improved electrical characteristics and reliability. When the plasma ashing process is executed at a relatively low temperature, the mask structure may be efficiently removed from the conductive pattern by adjusting a pressure of a process chamber, an applied bias power and a flow rate of a source gas.

### BRIEF DESCRIPTION OF THE DRAWINGS

Example embodiments will be more apparent from the following description with reference to the accompanying drawings, in which:

FIGS. 1 to 7 are cross-sectional views illustrating a method of forming a conductive pattern in a semiconductor device according to example embodiments;

FIGS. 8 to 17 are cross-sectional views illustrating a method of manufacturing a non-volatile semiconductor device according to example embodiments;

FIGS. 18 to 22 are cross-sectional views illustrating a method of manufacturing a volatile semiconductor device according to example embodiments;

FIG. 23 is a graph illustrating removal rates of masks relative to process temperatures in an oxygen plasma ashing process according to example embodiments;

FIG. 24 is a graph illustrating removal rates of masks relative to bias powers in an oxygen plasma ashing process according to example embodiments;

FIG. 25 is a graph illustrating removal rates of masks relative to flow rates of reaction gases including oxygen in an oxygen plasma ashing process according to example embodiments; and

FIG. 26 is a graph illustrating removal rates of masks relative to process pressures in an oxygen plasma ashing process according to example embodiments.

### DESCRIPTION OF EMBODIMENTS

Example embodiments are described more fully hereinafter with reference to the accompanying drawings. The invention may, however, be embodied in many different forms and should not be construed as limited to the example embodiments set forth herein. In the drawings, the sizes and relative sizes of layers and regions may be exaggerated for clarity.

It will be understood that when an element or a layer is referred to as being “on,” “connected to” or “coupled to” another element or layer, it can be directly on, connected to or coupled to the other element or layer or intervening elements or layers may be present. In contrast, when an element or a layer is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms “first”, “second”, “third” etc. may be used herein to describe various elements, components, regions, layers, patterns and/or sections, these elements, components, regions, layers, patterns and/or sections should not be limited by these terms. These terms are only used to distinguish one element, component, region, layer pattern or section from another element, component, region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the example term “below” can encompass both an orientation of above and below. The device may be otherwise oriented (e.g., rotated 90 degrees or at other orientations) and the spatially relative descriptors used herein interpreted accordingly.

The terminology used herein is for the purpose of describing particular example embodiments only and is not intended to be limiting. As used herein, the singular terms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of illustratively idealized example embodiments and intermediate structures. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle can have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the relevant art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

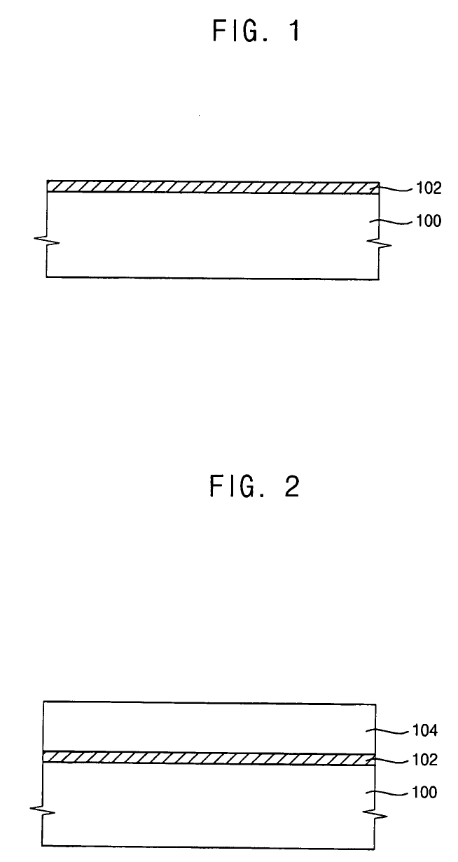

FIGS. 1 to 7 are cross-sectional views illustrating a method of forming a conductive pattern in a semiconductor device according to example embodiments.

Referring to FIG. 1, a conductive layer 102 including a metal is formed on a substrate 100. The substrate 100 may include a silicon-on-insulator (SOI) substrate, a germanium-on-insulator (GOI) substrate or a semiconductor substrate such as a silicon substrate, a germanium substrate, a silicon germanium substrate, etc.

In example embodiments, an under structure including a conductive pattern, an impurity region, a pad, a plug and/or an insulation layer pattern may be provided on the substrate 100.

The conductive layer 102 including a metal may be formed using a metal and/or a metal compound. Examples of the metal in the conductive layer 102 may include tungsten (W), aluminum (Al), cobalt (Co), titanium (Ti), tantalum (Ta), copper (Cu), etc. Examples of the metal compound in the conductive layer 102 may include tantalum nitride (TaNx), titanium nitride (TiNx), aluminum nitride (AlNx), tungsten nitride (WNx), etc. These materials may be used alone or in a mixture thereof. Further, the conductive layer 102 may be formed by a sputtering process, a chemical vapor deposition (CVD), an atomic layer deposition (ALD), a pulsed laser deposition (PLD) process, an evaporation process, etc.

In example embodiments, the conductive layer 102 may have a single layer structure or a multi layer structure. For example, the conductive layer 102 may include a metal film or a metal compound film. Alternatively, the conductive layer 102 may include a metal nitride film and a metal nitride film formed on the metal film.

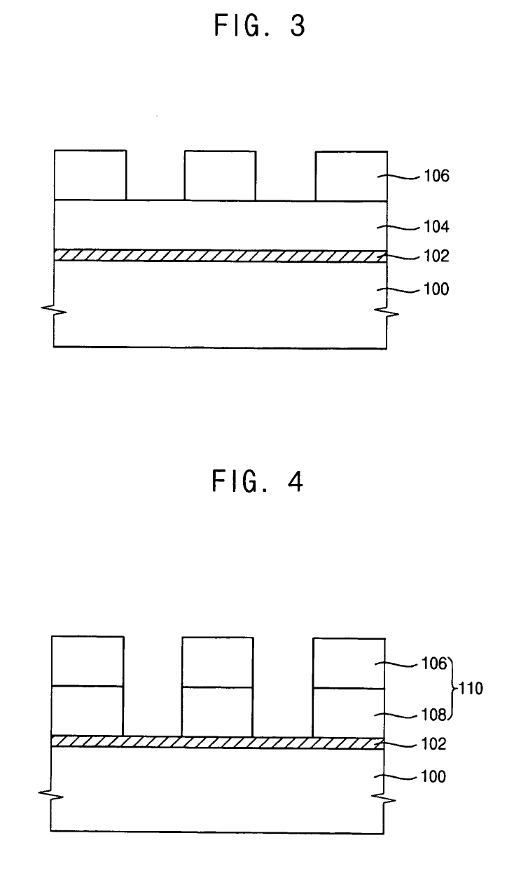

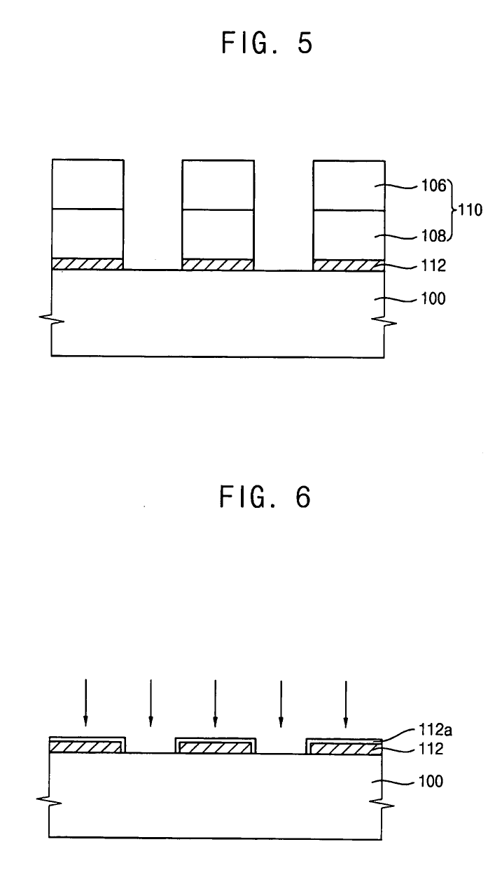

Referring to FIG. 2, an amorphous carbon layer 104 is formed on the conductive layer 102. The amorphous carbon layer 104 may be formed by a CVD process, an ALD process, a plasma enhanced chemical vapor deposition (PECVD) process, etc. The amorphous carbon layer 104 and a photoresist pattern 106 (see FIG. 3) may serve as a mask structure 110 (see FIG. 5) for forming a conductive pattern 112 (see FIG. 5).

Referring to FIG. 3, the photoresist pattern 106 is provided on the amorphous carbon layer 104 through a photo process. In the formation of the photoresist pattern 106, a photoresist film may be coated on the amorphous carbon layer 104 using an apparatus for coating photoresist such as a spinner. The coated photoresist film may be exposed to light using a photo mask having a desired pattern installed in an exposure apparatus such as a stepper or a scanner. The exposed photoresist film may be developed to provide the photoresist pattern 106 on the amorphous carbon layer 104.

Referring to FIG. 4, the amorphous carbon layer 104 is partially etched using the photoresist pattern 106 as an etching mask to form an amorphous carbon layer pattern 108 on the conductive layer 102. Thus, the mask structure 110 is provided on the conductive layer 102. The mask structure 110 includes the amorphous carbon layer pattern 108 and the photoresist pattern 106.

Referring to FIG. 5, the conductive layer 102 is partially etched using the mask structure 110 as an etching mask, so that a conductive pattern 112 is formed on the substrate 100. In example embodiments, an etching process for forming the conductive pattern 112 may include an anisotropic etching process. For example, the etching process may include a plasma etching process.

Referring to FIG. 6, the mask structure 110 is removed from the conductive pattern 112. In example embodiments, the mask structure 110 may be removed by an oxygen plasma ashing process using a source gas including oxygen.

In the plasma ashing process according to example embodiments, the substrate 100 having the conductive pattern 112 and the mask structure 110 may be introduced a process chamber. The process chamber may have a pressure of about 100 mTorr to about 300 mTorr. Further, the process chamber may be at a relatively high process temperature of about 65° C. to about 250° C.

While performing the plasma ashing process over the substrate 100, the source gas including oxygen gas may be introduced into the process chamber and a bias power may be applied to the source gas. Hence, an oxygen plasma may be generated in the process chamber over the substrate 100. For example, the source gas may have a flow rate of about 20 sccm to about 100 sccm, and the bias power may be in a range of about 20 W to about 100 W. Alternatively, the oxygen plasma may be generated by a remote plasma process.

In example embodiments, oxygen ions and oxygen radicals may be generated from a remote plasma generator, and then the oxygen ions may be selectively filtered from the oxygen plasma while supplying the oxygen ions and the oxygen radicals into the process chamber through a supply line. Thus, the oxygen radicals may be provided to the substrate 100 placed in the process chamber.

When the process chamber is at the relatively high process temperature, the oxygen radicals may react with carbon atoms in the amorphous carbon layer pattern 108 of the mask structure 110 to generate gaseous reaction byproducts such as a carbon monoxide (CO) gas and/or a carbon dioxide (CO₂) gas. The reaction byproducts may be exhausted from the process chamber using a discharging member such as a pump. Therefore, the mask structure 110 may be easily removed from the conductive pattern 112.

In the removal of the mask structure 110, the oxygen radicals may easily react with the carbon atoms in the amorphous carbon layer pattern 108, and the oxygen radicals may also react with metal atoms included in the conductive pattern 112. As a result, the conductive pattern 112 may have an oxidized portion 112a formed in the plasma ashing process. That is, a portion of the conductive pattern 112 exposed by the mask structure 110 may be oxidized by the oxygen radicals in the plasma ashing process.

In some example embodiments, the process chamber may have a pressure of about 10 mTorr to about 100 mTorr in the plasma ashing process for removing the mask structure 110 from the conductive pattern 112. Further, the process chamber may be at a relatively low process temperature of about 5° C. to about 65° C.

While performing the plasma ashing process, a source gas including oxygen may be introduced into the process chamber, and a bias power may be applied to the source gas. For example, the source gas may be provided to the substrate 100 with a flow rate of about 100 sccm to about 500 sccm, and the bias power may be in a range of about 100 W to about 500 W. Thus, an oxygen plasma may be generated over the substrate 100 positioned in the process chamber. Alternatively, the oxygen plasma may be generated from the source gas using an induced coupled plasma (IPC) apparatus.

In the plasma ashing process according to example embodiments, the oxygen ions and the oxygen radicals may be generated using a plasma generator at the relatively low process temperature. The oxygen ions and the oxygen radicals may react with carbon atoms included in the amorphous carbon layer pattern 108 more rapidly than they do with the metal atoms included in the conductive pattern 112. Therefore, oxidization of the conductive pattern 112 may be prevented when the plasma ashing process is performed at the relatively low process temperature.

When the plasma ashing process is executed at the relatively low process temperature, a process time for removing the mask structure 110 may increase. To reduce the process time, the mask structure 110 may be removed by colliding the mask structure 110 with the oxygen ions and the oxygen radicals, alternatively or additionally to using the reaction between the oxygen radicals and the carbon atoms when the flow rate of the source gas provided into the process chamber and the bias power are increased and the pressure of the process chamber is reduced. For example, the oxygen ions and the oxygen radicals may be strongly induced onto the substrate 100 when the bias power and the flow rate of the source gas are increased. The strongly induced oxygen ions and radicals may more rapidly remove the mask structure 110 from the conductive pattern 112. Further, the oxidation of the conductive pattern 112 may be substantially prevented because the oxygen ions and the oxygen radicals may not sufficiently react with the metal atoms in the conductive pattern 112.

In example embodiments, the mask structure 110 may be mainly removed by the chemical reaction between the oxygen radicals and the carbon atoms when the plasma ashing process is carried out at the relative high process temperature.

When the plasma ashing process is executed at the relatively low process temperature, the mask structure 110 may be removed through the collision of the oxygen ions and radicals. The chemical reaction may be dominant at the relatively high process temperature, whereas use of the collision may increase at the relatively low process temperature.

In some example embodiments, a stripping process may be performed over the substrate 100 to efficiently remove the mask structure 110 from the conductive pattern 112 after the plasma ashing process.

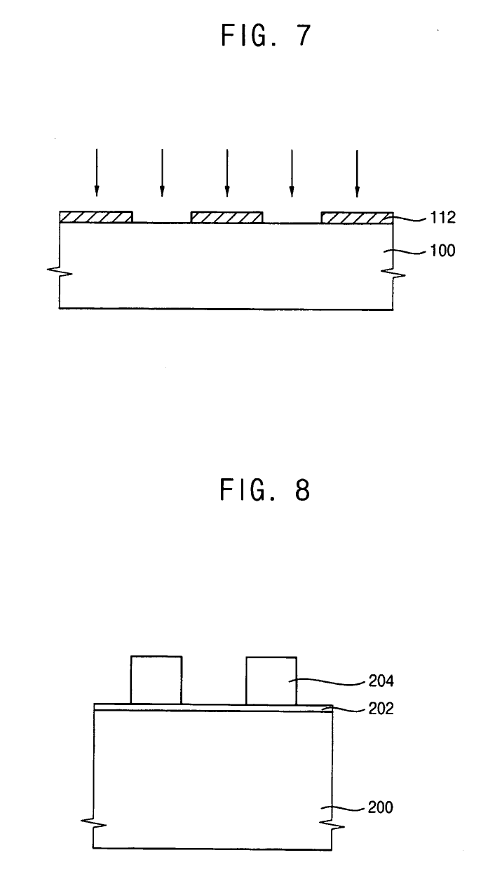

Referring to FIG. 7, a reduction process is executed on the conductive pattern having the oxidized portion 112a when the conductive pattern 112 has the oxidized portion 112a formed in the plasma ashing process.

In the reduction process according to example embodiments, the substrate 100 having the conductive pattern 112 may be placed in a process chamber. The reduction process may be performed using the process chamber substantially the same as that employed in the plasma ashing process. The plasma ashing process and the reduction process may be executed in-situ. A reaction gas including hydrogen may be introduced into the process chamber having the substrate 100. For example, the reaction gas may be provided with a flow rate of about 10 sccm to about 500 sccm. Examples of the reaction gas may include hydrogen (H₂) gas and/or ammonia (NH₃) gas. The reaction gas may react with oxygen atoms in the oxidized portion 112a of the conductive pattern 112 to generate gaseous reaction byproducts such as water vapor. The reaction byproducts may be exhausted from the process chamber using a discharging member such as a pump. As a result, the oxidized portion 112a of the conductive pattern 112 may be reduced.

When the mask structure 110 is removed by the above-described plasma ashing process, the conductive pattern 112 having the oxidized portion 112a may have a resistance substantially larger than a desired resistance of the conductive pattern 112 because the oxidized portion 112a of the conductive pattern 112 may include oxygen atoms. When the reduction process is performed on the oxidized portion 112a of the conductive pattern 112, the conductive pattern 112 may have the desired resistance by reducing the oxidized portion 112a.

As described above, when the bias power and the flow rate of the source gas including oxygen provided in the process chamber are increased and the pressure of the process chamber is reduced, the oxidation of the conductive pattern 112 may be substantially prevented because the collision between the mask structure 100 and the reaction gas including the oxygen ions and the oxygen radicals may increase. The reduction process may be executed on the oxidized portion 112a of the conductive pattern 112 on the substrate 100 when the conductive pattern 112 has the oxidized portion 112a caused by the plasma ashing process.

FIGS. 8 to 17 are cross-sectional views illustrating a method of manufacturing a non-volatile semiconductor device in accordance with example embodiments. Although FIGS. 8 to 17 illustrate the method of manufacturing the non-volatile memory device, e.g., a NAND type flash memory device having a self-aligned shallow trench isolation (SA-STI) structure, other non-volatile semiconductor devices such as planar type non-volatile memory devices may be manufactured through the method illustrated in FIGS. 8 to 17.

Referring to FIG. 8, a pad oxide layer 202 and a first mask 204 are formed on a substrate 200. The substrate 200 may include a semiconductor substrate such as a silicon substrate, a germanium substrate, a silicon germanium substrate, etc. Alternatively, the substrate 200 may include an SOI substrate, a GOI substrate, etc.

The pad oxide layer 102 may reduce stress generated between the substrate 200 and the first mask 204. The pad oxide layer 102 may include silicon oxide formed through a thermal oxidation process or a CVD process.

The first mask 204 is positioned on the pad oxide layer 202. The first mask 204 may be formed using a material that has an etching selectivity relative to the pad oxide layer 202 and the substrate 200. For example, the first mask 204 may include a nitride (such as silicon nitride) or an oxynitride (such as silicon oxynitride). The first mask 204 may be formed by a CVD process, an ALD process, a low pressure chemical vapor deposition (LPCVD) process, a PECVD process, etc.

In example embodiments, the first mask 204 may be formed on the pad oxide layer 202 by patterning a first mask layer (not illustrated) after forming the first mask layer on the pad oxide layer 202. The first mask 204 may extend over the substrate 200 in a first direction.

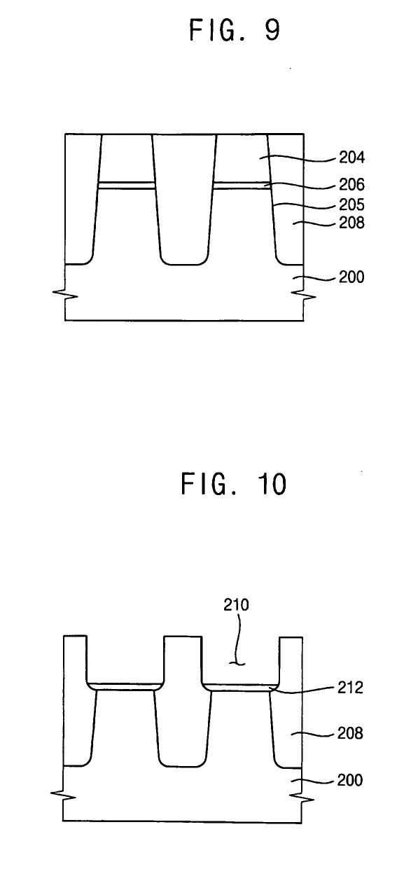

Referring to FIG. 9, the pad oxide layer 202 and the substrate 100 are partially etched using the first mask 204 as an etching mask. Thus, a pad oxide layer pattern 206 and a trench 205 are formed on the substrate 200. The trench 205 may have a predetermined depth from an upper face of the substrate 200. Further, the trench 205 may have a sidewall inclined by a predetermined angle relative to the substrate 100. The trench 205 may have an upper width substantially larger than a lower width.

A field isolation layer (not illustrated) is formed on the first mask 204 to fill the trench 205. The field isolation layer may efficiently fill the trench 205. The field isolation layer may be formed using an oxide such as silicon oxide. Examples of silicon oxide in the field isolation layer may include undoped silicate glass (USG), spin on glass (SOG), flowable oxide (FOX), plasma enhanced-tetraethyl ortho silicate (PE-TEOS), tonen silazene (TOSZ), fluorosilicate glass (FSG), high density plasma-chemical vapor deposition (HDP-CVD) oxide, etc. Further, the field isolation layer may be formed by a CVD process, PECVD process, a spin coating process, an HDP-CVD process, etc.

The field isolation layer is partially removed until the first mask 204 is exposed, so that a field isolation layer pattern 208 is formed in the trench 205. Further, the field isolation layer pattern 208 fills a gap between adjacent first masks 204. Thus, upper faces of the field isolation layer pattern 208 and the first mask 204 may exist on a same plane. The field isolation layer pattern 208 may be formed by a chemical mechanical polishing (CMP) process and/or an etch-back process.

Referring to FIG. 10, the first mask 204 and the pad oxide layer pattern 206 are removed from the substrate 200. Hence, an opening 210 defined by adjacent field isolation layer patterns 208 is provided at a position where the first mask 204 and the pad oxide layer pattern 206 were formed. When the opening 210 is formed between adjacent field isolation layer patterns 208, a portion of the substrate 200 between adjacent field isolation layer patterns 208 is exposed.

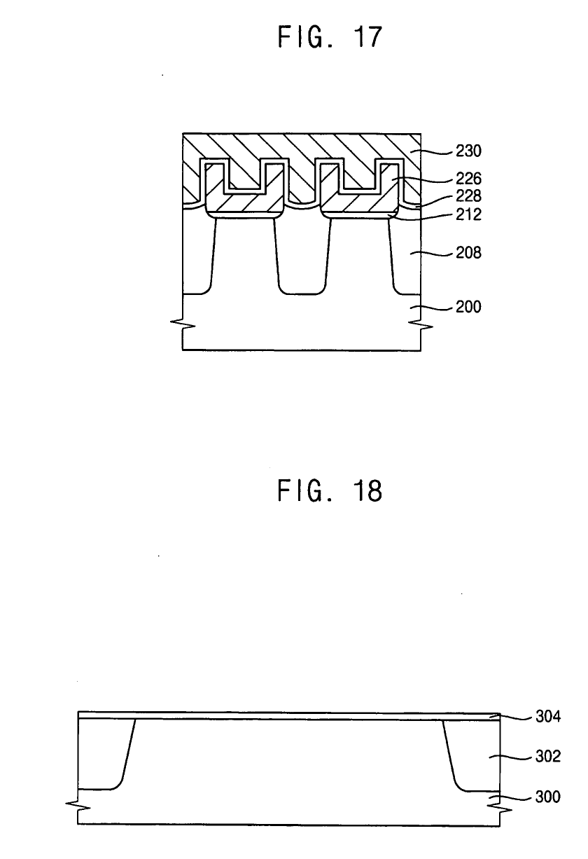

In example embodiments, an upper sidewall of the field isolation layer pattern 208 may be partially etched while removing the first mask 204 and the pad oxide layer pattern 206. A width of the opening 210 may be enlarged, and the field isolation layer pattern 208 may have an upper width substantially smaller than a lower width. When the opening 210 has the enlarged width, a floating gate 226 (see FIG. 17) formed in the opening 210 may also have an increased width.

A tunnel insulation layer 212 is formed on the portion of the substrate 200 exposed by the opening 210. The tunnel insulation layer 212 may be formed using silicon oxide, silicon oxynitride, a metal oxide, etc. Examples of the metal oxide in the tunnel insulation layer 212 may include aluminum oxide (AlOx), hafnium oxide (HfOx), hafnium silicon oxide (HfSixOy), hafnium aluminum oxide (HfAlxOy), hafnium lanthanum oxide (HfLaxOy), zirconium oxide (ZrOx), zirconium silicon oxide (ZrSixOy), etc.

When the width of the opening 210 is increased, the tunnel insulation layer 212 may be formed on a portion of the upper sidewall of the field isolation layer patter 208 besides the exposed portion of the substrate 200.

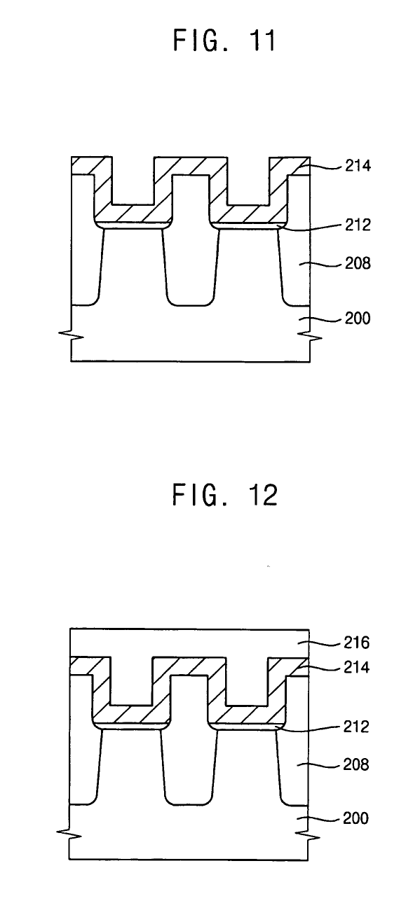

Referring to FIG. 11, a first conductive layer 214 is formed on the tunnel insulation layer 212 and the field isolation layer pattern 208. The first conductive layer 214 may be conformally formed along profiles of the field isolation layer pattern 208 and the tunnel insulation layer 212, so the first conductive layer 214 may have a uniform thickness. The first conductive layer 214 may partially fill the opening 210 between adjacent field isolation layer patterns 208.

In example embodiments, the first conductive layer 214 may be formed using polysilicon, a metal and/or a metal compound. For example, the first conductive layer 214 may include polysilicon doped with impurities, tungsten (W), aluminum (Al), cobalt (Co), copper (Cu), titanium (Ti), tantalum (Ta), tungsten nitride (WNx), aluminum nitride (AlNx), titanium nitride (TiNx), tantalum nitride (TaNx), etc. These materials may be used alone or in a mixture thereof. Further, the first conductive layer 214 may be formed through a sputtering process, a CVD process, an ALD process, a PLD process, an electron-beam evaporation process, etc.

Referring to FIG. 12, a sacrificial layer 216 is formed on the first conductive layer 214 to fully fill the opening 210. The sacrificial layer 216 may be formed using a photoresist. Alternatively, the sacrificial layer 216 may be formed using an oxide such as silicon oxide. For example, the sacrificial layer 216 may include USG, SOG, boro-phosphor silicate glass (BPSG), phosphor silicate glass (PSG), FOX, TEOS, PE-TEOS, TOSZ, FSG, HDP-CVD oxide, etc.

In example embodiments, the sacrificial layer 216 may include an oxide substantially the same as or substantially similar to that of the field isolation layer pattern 208. Alternatively, the sacrificial layer 216 and the field isolation layer pattern 208 may include different oxides.

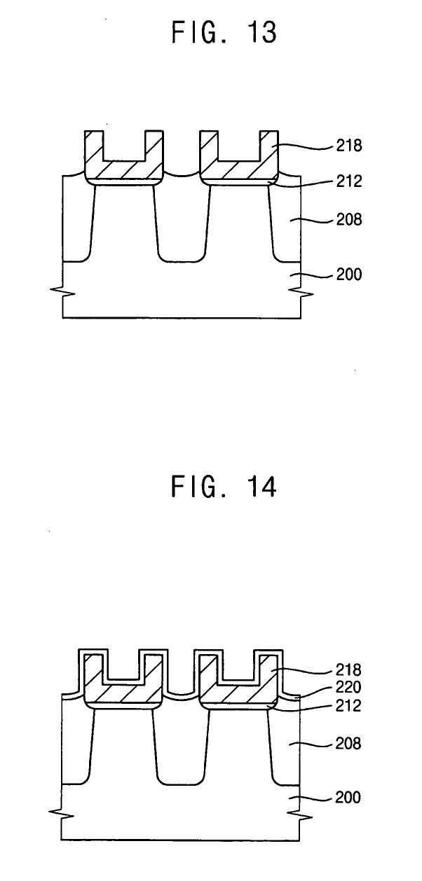

Referring to FIG. 13, the sacrificial layer 216 is partially removed until the first conductive layer 214 is exposed to form a sacrificial layer pattern (not illustrated) in the opening 210. The sacrificial layer pattern may be formed by a CMP process and/or an etch-back process. The sacrificial layer pattern may also fill the opening 210.

The first conductive layer 214 is partially removed until the field isolation layer pattern 208 is exposed and a preliminary floating gate 218 is formed on the tunnel insulation layer 212. The preliminary floating gate 218 may be formed through a CMP process and/or an etch-back process.

In example embodiments, the preliminary floating gate 218 may have a cross-section of a U shape. When the sacrificial layer pattern is removed, the preliminary floating gate 218 may protrude from the tunnel insulation layer 212 along an upward direction relative to the substrate 200.

After the formation of the preliminary floating gate 218, the sacrificial layer pattern is removed from the preliminary floating gate 218. When the sacrificial layer pattern includes oxide, the field isolation layer pattern 208 may be partially etched while removing the sacrificial layer pattern. A lower sidewall of the preliminary floating gate electrode 218 may be exposed when the field isolation layer pattern 208 is partially removed. Thus, a contact area between the preliminary floating gate 218 and a dielectric layer 220 (see FIG. 14) may increase because the dielectric layer 220 covers the preliminary floating gate 218 having an exposed lower sidewall. As a result, a coupling ratio of the non-volatile semiconductor device may be improved to provide high electrical characteristics.

Referring to FIG. 14, the dielectric layer 220 is formed on the preliminary floating gate 218 and the field isolation layer pattern 208. The dielectric layer 220 may be conformally formed along profiles of the preliminary floating gate 218 and the field isolation layer pattern 208. The dielectric layer 220 may be formed by a CVD process, a PECVD process, a sputtering process, an ALD process, an evaporation process, etc. Further, the dielectric layer 220 may be formed using an oxide, a nitride and/or a metal oxide having a high dielectric constant. For example, the dielectric layer 220 may include silicon oxide, silicon nitride, aluminum oxide (AlOx), yttrium oxide (YOx), niobium oxide (NbOx), hafnium oxide (HfOx), zirconium oxide (ZrOx), tantalum oxide (TaOx), barium titanium oxide (BaTixOy), strontium titanium oxide (SrTixOy), etc. These materials may be used alone or in a mixture thereof.

The dielectric layer 220 may have a single layer structure that includes an oxide film, a nitride film or a metal oxide film. Alternatively, the dielectric layer 220 may have a multi layer structure that includes an oxide film, a nitride film and/or a metal oxide film. For example, the dielectric layer 220 may have a lower oxide film/a nitride film/an upper oxide film (ONO) structure.

Referring to FIG. 15, a second conductive layer 222 is formed on the dielectric layer 220. The second conductive layer 222 may be formed using doped polysilicon, a metal and/or a metal compound. For example, the second conductive layer 222 may include polysilicon doped with impurities, tungsten (W), aluminum (Al), cobalt (Co), copper (Cu), titanium (Ti), tantalum (Ta), tungsten nitride (WNx), aluminum nitride (AlNx), titanium nitride (TiNx), tantalum nitride (TaNx), etc. These materials may be used alone or in a mixture thereof. The second conductive layer 222 may be formed by a sputtering process, a CVD process, an LPCVD process, a PLD process, an ALD process, an evaporation process, etc.

In example embodiments, the second conductive layer 222 may have a thickness that sufficiently covers the dielectric layer 220 and the preliminary floating gate 218. Further, an upper portion of the second conductive layer 222 may be planarized by a planarization process, so the second conductive layer 222 may have a level upper face. For example, the upper portion of the second conductive layer 222 may be planarized by a CMP process and/or an etch-back process.

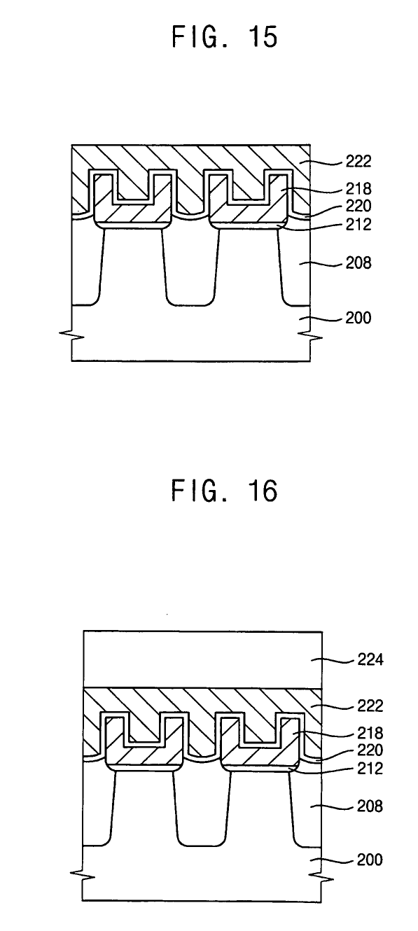

Referring to FIG. 16, a second mask 224 is provided on the second conductive layer 222. The second mask 224 may extend on the second conductive layer 222 along a second direction substantially perpendicular to the first direction. The second mask 224 may be formed using silicon nitride, silicon oxynitride, amorphous carbon, photoresist, etc. The second mask 224 may have a single layer structure or a multi layer structure. For example, the second mask 224 may include an amorphous carbon layer pattern film and a photoresist pattern.

Referring to FIG. 17, the second conductive layer 222, the dielectric layer 220 and the preliminary floating gate 218 are etched using the second mask 224 as an etching mask. Thus, a floating gate 226, a dielectric layer pattern 228 and a control gate 230 are successively formed on the tunnel insulation layer 212.

In example embodiments, the floating gate 226 is positioned between the tunnel insulation layer 212 and the dielectric layer pattern 228. The floating gate 226 may have a hexahedral structure. Adjacent floating gates 226 may be separated from each other. The dielectric layer pattern 228 and the control gate 230 may have line or bar structures, respectively.

The dielectric layer pattern 228 and the control gate 230 may extend over the substrate 200 along the second direction. After the formations of the floating gate 226, the dielectric layer pattern 228 and the control gate 230, the second mask 224 is removed from the control gate 230.

In example embodiments, the second mask 224 may be removed by a plasma ashing process using an oxygen plasma when the control gate 230 includes metal and the second mask 224 includes carbon. The plasma ashing process for removing the second mask 224 may be substantially the same as or substantially similar to the plasma ashing process described with reference to FIG. 6.

In example embodiments, an upper portion of the control gate 230 may be oxidized while removing the second mask 224 by the plasma ashing process. Namely, a portion of the control gate 230 exposed by the second mask 224 may be oxidized in the plasma ashing process. Hence, a reduction process may be executed on an oxidized portion of the control gate 230 when the control gate 230 includes the oxidized portion. The reduction process for reducing the oxidized portion of the control gate 230 may be substantially the same as or substantially similar to the reduction process described with reference to FIG. 7.

After the second mask 224 is removed by the plasma ashing process, the reduction process may be performed on the oxidized portion of the control gate 230, so that the control gate 230 may have a desired resistance to provide improved electrical characteristics and reliability of the non-volatile semiconductor device.

FIGS. 18 to 22 are cross-sectional views illustrating a method of manufacturing a volatile semiconductor device according to example embodiments. FIGS. 18 to 22 illustrate the method of manufacturing the volatile semiconductor device such as a DRAM device. However, other volatile semiconductor devices such as SRAM devices may be manufactured through the method according to example embodiments.

Referring to FIG. 18, a field isolation layer 302 is formed on a substrate 300 to define an active region and a field region of the substrate 300. The substrate 300 may include a semiconductor substrate, an SOI substrate, a GOI substrate, etc. The field isolation layer 302 may be formed using an oxide such as silicon oxide. The field isolation layer 302 may be formed using an oxide by an isolation process such as a shallow trench isolation process or a thermal oxidation process.

A gate insulation layer 304 is formed on the substrate 200 having the active region and the field region. The gate insulation layer 304 may be formed using an oxide such as silicon oxide by a CVD process or a thermal oxidation process. Alternatively, the gate insulation layer 304 may be formed using a metal oxide such as hafnium oxide, zirconium oxide, aluminum oxide, tantalum oxide, etc. The gate insulation layer 304 may be formed by a CVD process, an ALD process, a PLD process, a sputtering process, etc.

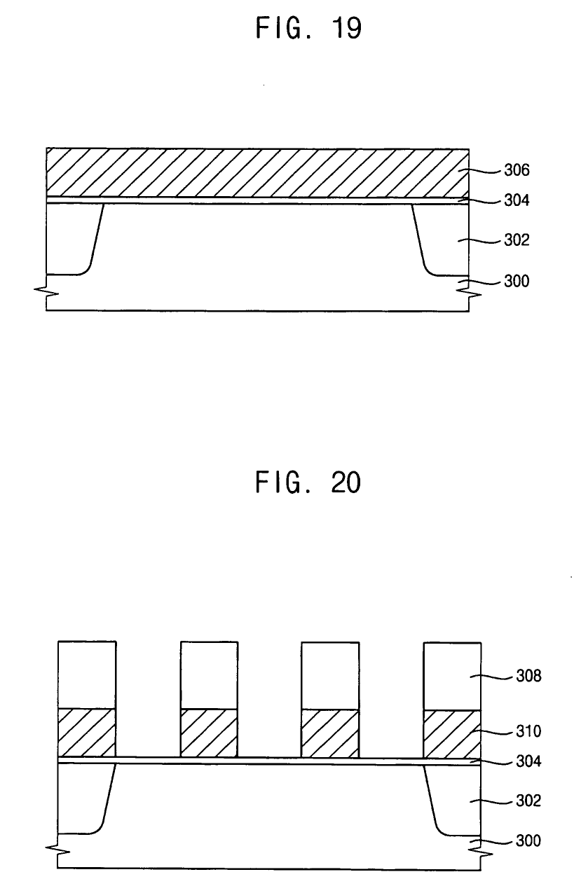

Referring to FIG. 19, a conductive layer 306 is formed on the gate insulation layer 304. The conductive layer 306 may be formed using doped polysilicon, a metal and/or a metal compound. For example, the conductive layer 306 may include polysilicon doped with impurities, tungsten, aluminum, cobalt, copper, titanium, tantalum, tungsten nitride, aluminum nitride, titanium nitride, tantalum nitride, etc. These materials may be used alone or in a mixture thereof. Further, the conductive layer 306 may be formed by a sputtering process, an ALD process, a CVD process, a PECVD process, an evaporation process, etc.

Referring to FIG. 20, a mask 308 is formed on the conductive layer 306. The mask 308 may have a multi layer structure that includes an amorphous carbon film pattern and a photoresist pattern. The mask 308 may extend on the substrate 300 in a first direction. For example, adjacent masks 308 may have line or bar structures extending in parallel.

The conductive layer 308 is etched using the mask 308 as an etching mask, such that a gate electrode 310 is formed on the gate insulation layer 304. The gate electrode 310 may extend on the gate insulation layer 304 along a direction substantially the same as that of the mask 308. That is, the gate electrode 310 may extend in the first direction.

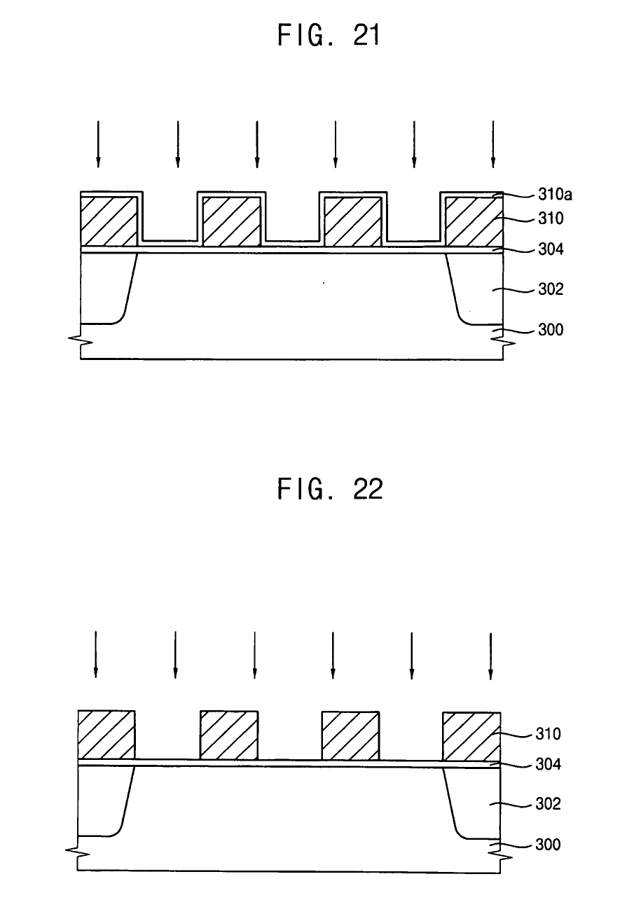

Referring to FIG. 21, the mask 308 is removed from the gate electrode 310. The mask 308 may be removed from the gate electrode 310 by a plasma ashing process using an oxygen plasma. The plasma ashing process for removing the mask 308 may be substantially the same as or substantially similar to the plasma ashing process described with reference to FIG. 6.

In example embodiments, a stripping process may be additionally performed over the substrate 300 having the gate electrode 310 to efficiently remove the mask 308 from the gate electrode 310.

In example embodiments, a portion of the gate electrode 310 may be oxidized while removing the mask 308 by the plasma ashing process. Thus, the gate electrode 310 may have an oxidized portion 310a.

Referring to FIG. 22, a reduction process is executed on the oxidized portion 310a of the gate electrode 310 when the gate electrode 310 has the oxidized portion 310a caused by the plasma ashing process. The reduction process for reducing the oxidized portion 310a of the gate electrode 310 may be carried out using a reaction gas including hydrogen gas and/or ammonia gas. The reduction process for reducing the oxidized portion 310a of the gate electrode 310 may be substantially the same as or substantially similar to the reduction process described with reference to FIG. 7.

After the mask 308 is removed by the plasma ashing process, the reduction process may be performed on the oxidized portion 310a of the gate electrode 310, so that the gate electrode 310 may have a desired resistance. Thus, the volatile semiconductor device including the gate electrode 310 may have enhanced reliability and electrical characteristics.

Hereinafter, a plasma ashing process according to example embodiments will be described in detail with reference to the accompanying drawings. The plasma ashing process may depend on various process conditions such as a process temperature, a process pressure, a bias power, and/or a flow rate of a source gas. The plasma process may be performed using an induced coupled plasma (IPC) apparatus.

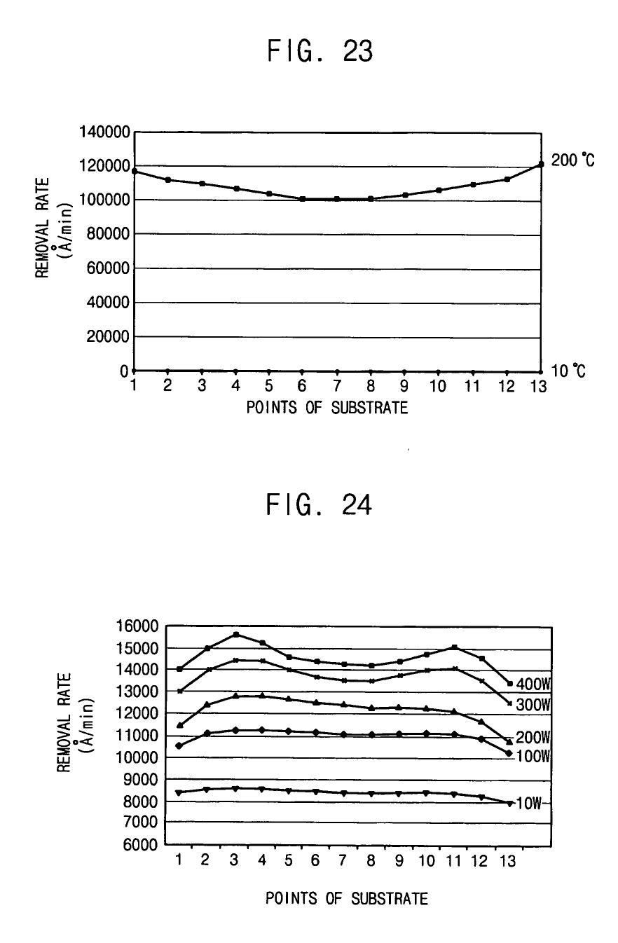

FIG. 23 is a graph illustrating removal rates of masks relative to process temperatures in an oxygen plasma ashing process according to example embodiments. In FIG. 23, the removal rates of the masks including amorphous carbon layer patterns and photoresist patterns are measured at process temperatures of about 200° C. and about 10° C. while constantly maintaining the process pressure, the bias power and the flow rate of the source gas including oxygen in a process chamber of the IPC apparatus. The removal rates of the masks are detected at thirteen points of a substrate where a conductive pattern including metal is formed.

Referring to FIG. 23, the removal rates of the masks are in a range of about 100,600 Å/min to about 122,000 Å/min when the process temperature is about 200° C. However, the removal rates of the masks are in a range of about 400 Å/min to about 530 Å/min when the process temperature is about 10° C. That is, the removal rate of the mask increases as the process temperature of the plasma ashing process increases. However, oxygen ions and/or oxygen radicals may be strongly induced onto the substrate when the process temperature is relatively high. These oxygen ions and/or the oxygen radicals may oxidize a portion of the conductive pattern including metal atoms exposed by the mask while removing the mask by the plasma ashing process.

FIG. 24 is a graph illustrating removal rates of masks relative to bias powers in an oxygen plasma ashing process according to example embodiments. In FIG. 24, the removal rates of the masks including amorphous carbon layer patterns and photoresist pattern are measured at process bias powers of about 0 W, about 100 W, about 200 W, about 300 W and about 400 W while constantly maintaining the process temperature, the pressure, and the flow rate of the source gas including oxygen in the process chamber of the IPC apparatus. The removal rates of the masks are detected at thirteen points of a substrate on which a conductive pattern including metal is formed.

Referring to FIG. 24, the removal rates of the masks are in a range of about 7,900 Å/min to about 9,600 Å/min at the process bias power of about 0 W, and the removal rates of the masks are in a range of about 10,200 Å/min to about 11,300 Å/min when the process bias power is about 100 W. Additionally, the removal rates of the mask are in a range of about 10,800 Å/min to about 12,900 Å/min at the process bias power of about 200 W, and the removal rates of the masks are in a range of about 12,500 Å/min to about 14,500 Å/min when the process bias power is about 300 W. Furthermore, the removal rates of the mask are in a range of about 13,400 Å/min to about 15,700 Å/min when the process bias power is about 400 W. That is, the removal rate of the mask increases as the process bias power of the plasma ashing process increases.

Oxygen ions and/or oxygen radicals may be strongly induced onto the substrate when the process bias power is relatively high. The oxygen ions and/or the oxygen radicals may easily react with carbon atoms in the mask, and thus the mask may be more rapidly removed from the conductive pattern including metal.

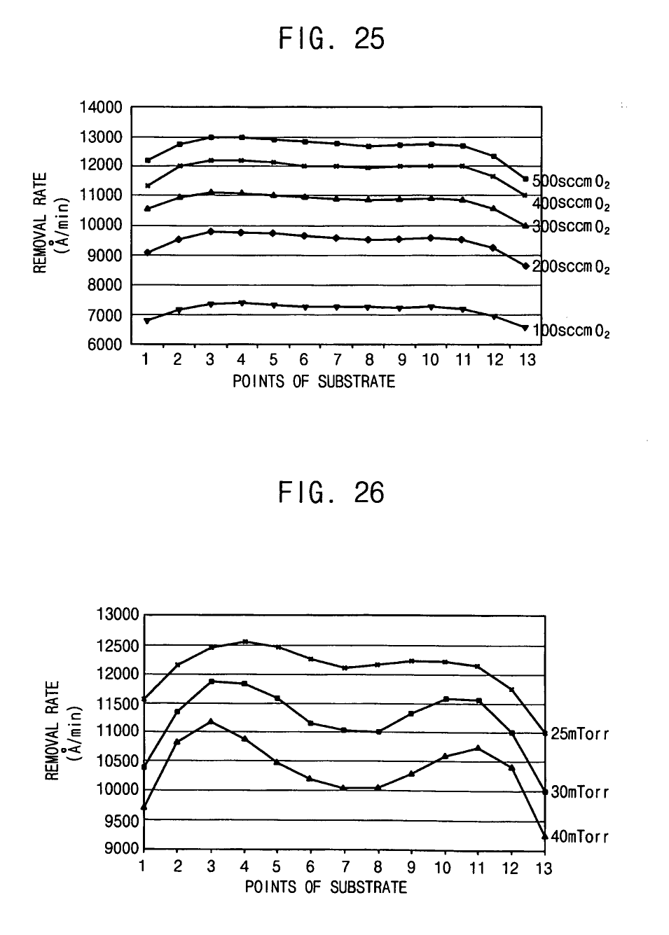

FIG. 25 is a graph illustrating removal rates of masks relative to flow rates of source gases including oxygen in an oxygen plasma ashing process according to example embodiments. In FIG. 25, the removal rates of the masks including amorphous carbon layer patterns and photoresist patterns are measured at flow rates of the source gas including oxygen of about 100 sccm, about 200 sccm, about 300 sccm and about 400 sccm while constantly maintaining the process temperature, the bias power and the pressure in the process chamber of the IPC apparatus. The removal rates of the masks are detected at thirteen points of a substrate having a conductive pattern including metal thereon.

Referring to FIG. 25, the removal rates of the masks are in a range of about 6,500 Å/min to about 7,400 Å/min at the flow rate of the source gas including oxygen of about 100 sccm, and the removal rates of the masks are in a range of about 8,650 Å/min to about 9,800 Å/min when the flow rate of the source gas including oxygen is about 200 sccm. Additionally, the removal rates of the masks are in a range of about 9,900 Å/min to about 11,200 Å/min at the flow rate of the source gas including oxygen of about 300 sccm, and the removal rates of the masks are in a range of about 10,900 Å/min to about 12,200 Å/min when the flow rate of the source gas including oxygen is about 300 sccm. Furthermore, the removal rates of the masks are in a range of about 11,500 Å/min to about 13,100 Å/min when the flow rate of the source gas including oxygen is about 500 sccm. That is, the removal rate of the mask increases as the flow rate of the source gas including oxygen of the plasma ashing process increases.

The oxygen ions and/or the oxygen radicals may be strongly induced onto the substrate when the flow rate of the source gas including oxygen is relatively high. The oxygen ions and/or the oxygen radicals may easily react with carbon atoms in the mask, so the mask may be more rapidly removed from the conductive pattern including metal.

FIG. 26 is a graph illustrating removal rates of masks relative to process pressures in an oxygen plasma ashing process according to example embodiments. In FIG. 26, the removal rates of the masks including amorphous carbon layer patterns and photoresist patterns are measured at process pressures of about 25 mTorr, about 30 mTorr and about 40 mTorr while constantly maintaining the process temperature, the bias power and the flow rate of the source gas including oxygen in the process chamber of the IPC apparatus. The removal rates of the masks are detected at thirteen points of a substrate where a conductive pattern including metal is formed.

Referring to FIG. 26, the removal rates of the masks are in a range of about 11,000 Å/min to about 12,600 Å/min at the process pressure of about 25 mTorr, and the removal rates of the masks are in a range of about 9,950 Å/min to about 11,900 Å/min when the process pressure is about 30 mTorr. Further, the removal rates of the mask are in a range of about 9,200 Å/min to about 11,200 Å/min at the process pressure of about 40 mTorr. That is, the removal rate of the mask increases as the process pressure of the plasma ashing process decreases.

The oxygen ions and/or the oxygen radicals may be strongly induced onto the substrate when the process pressure is relatively low. The oxygen ions and/or the oxygen radicals may easily react with carbon atoms in the mask, so the mask may be more rapidly removed from the conductive pattern including metal.

As described with reference to FIGS. 23 to 26, when the process chamber has the relatively low temperature, the oxygen ions and/or the oxygen radicals may be weakly induced onto the substrate having the conductive pattern including metal, and may slowly react with the carbon atoms in the mask during the plasma ashing process. However, when the oxygen ions and/or the oxygen radicals are weakly induced onto the substrate, the oxidation of the conductive pattern including metal may be substantially prevented. Meanwhile, the bias power and the flow rate of the source gas may be increased and the pressure of the process chamber may be reduced to substantially compensate for the decrease of the removal rate of the mask when the process chamber is at the relatively low temperature.

According to example embodiments, a mask structure having an amorphous carbon layer pattern and a photoresist pattern may be effectively removed from a conductive pattern including metal by a plasma ashing process after forming the conductive pattern using the mask structure. When the plasma ashing process is performed at a relatively high temperature, an oxidized portion of the conductive pattern caused by the plasma ashing process may be reduced by a reduction process. Thus, the conductive pattern may have a desired resistance, and a semiconductor device including the conductive pattern may have improved electrical characteristics and reliability. When the plasma ashing process is executed at a relatively low temperature, the mask structure may be efficiently removed from the conductive pattern by adjusting a pressure of a process chamber, an applied bias power and/or a flow rate of a source gas.

The foregoing is illustrative of example embodiments, and is not to be construed as limiting. Although example embodiments have been described, those skilled in the art will readily appreciate that many modifications are possible in the example embodiments without materially departing from the novel teachings and advantages of example embodiments. Accordingly, all such modifications are intended to be included within the scope of the claims. The invention is defined by the following claims, with equivalents of the claims to be included therein.

What is claimed is:

1. A method of forming a conductive pattern in a semiconductor device, comprising:
forming a conductive layer including a metal on a substrate;
forming a mask structure including carbon on the conductive layer;
forming the conductive pattern on the substrate by etching the conductive layer using the mask structure as an etching mask;
removing the mask structure by a plasma ashing process using a source gas including oxygen; and
reducing an oxidized portion of the conductive pattern formed in the plasma ashing process.

2. The method of claim 1, wherein forming the masks structure comprises:
forming an amorphous carbon layer pattern on the conductive layer; and
forming a photoresist pattern on the amorphous carbon layer pattern.

3. The method of claim 2, wherein the mask structure is removed at a temperature of about 5° C. to about 65° C., a flow rate of the source gas of about 100 sccm to about 500 sccm, and a pressure of about 10 mTorr to about 100 mTorr by applying a bias power of about 100 W to about 500 W.

4. The method of claim 2, wherein the mask structure is removed at a temperature of about 65° C. to about 250° C., a flow rate of the source gas of about 20 sccm to about 100 sccm, and a pressure of about 10 mTorr to about 300 mTorr by applying a bias power of about 20 W to about 100 W.

5. The method of claim 1, wherein reducing the oxidized portion of the conductive pattern is performed using a reaction gas including hydrogen.

6. The method of claim 5, wherein the reaction gas comprises at least one of hydrogen (H₂) gas and ammonia (NH₃) gas.

7. The method of claim 1, wherein the plasma ashing process is carried out using an induced couple plasma apparatus.

8. The method of claim 1, wherein removing the mask and reducing the oxidized portion of the conductive pattern are performed in-situ.

9. The method of claim 1, wherein the metal in the conductive layer comprises at least one selected from the group consisting of tungsten (W), aluminum (Al), cobalt (Co), copper (Cu), titanium (Ti) and tantalum (Ta).

10. The method of claim 1, wherein the conductive pattern comprises a metal nitride including at least one selected from the group consisting of tungsten nitride, aluminum nitride, titanium nitride, and tantalum nitride.

11. A method of manufacturing a semiconductor device, comprising:
forming a tunnel insulation layer on a substrate;
forming a preliminary floating gate on the tunnel insulation layer;
forming a dielectric layer on the preliminary floating gate;
forming a conductive layer including metal on the dielectric layer;
forming a mask including carbon on the conductive layer;
forming a control gate, a dielectric layer pattern and a floating gate by etching the conductive layer, the dielectric layer and the preliminary floating gate using the mask as an etching mask;
removing the mask from the control gate by an oxygen plasma ashing process; and
reducing an oxidized portion of the control gate formed in the oxygen plasma ashing process.

12. The method of claim 11, wherein forming the mask on the conductive layer comprises:
forming an amorphous carbon layer on the conductive layer;
forming a photoresist pattern on the amorphous carbon layer; and
forming an amorphous carbon layer pattern on the conductive layer by etching the amorphous carbon layer using the photoresist pattern as an etching mask.

13. The method of claim 12, wherein removing the mask from the control gate is performed at a temperature of about 5° C. to about 250° C., a flow rate of a source gas of about 20 sccm to about 500 sccm, and a pressure of about 10 mTorr to about 300 mTorr by applying a bias power of about 10 W to about 500 W.

14. The method of claim 11, wherein reducing the oxidized portion of the control gate is executed using a reaction gas including hydrogen.

15. The method of claim 14, wherein the reaction gas comprises at least one of hydrogen gas and ammonia gas.

16. A method of manufacturing a semiconductor device, comprising:
forming a gate insulation layer on a substrate;
forming a conductive layer including metal on the gate insulation layer;
forming a mask including carbon on the conductive layer;
forming a gate electrode on the gate insulation layer by etching the conductive layer using the mask as an etching mask;
removing the mask from the gate electrode by an oxygen plasma ashing process; and
reducing an oxidized portion of the gate electrode formed in the oxygen plasma ashing process.

17. The method of claim 16, wherein forming the mask on the conductive layer comprises:
forming an amorphous carbon layer on the conductive layer;
forming a photoresist pattern on the amorphous carbon layer; and
forming an amorphous carbon layer pattern on the conductive layer by etching the amorphous carbon layer using the photoresist pattern as an etching mask.

18. The method of claim 17, wherein removing the mask from the gate electrode is performed at a temperature of about 5° C. to about 250° C., a flow rate of a source gas of about 20 sccm to about 500 sccm, and a pressure of about 10 mTorr to about 300 mTorr by applying a bias power of about 10 W to about 500 W.

19. The method of claim 16, wherein removing the mask and reducing the oxidized portion of the gate electrode are performed in-situ.

20. The method of claim 16, wherein reducing the oxidized portion of the gate electrode is executed using a reaction gas including at least one of hydrogen gas and ammonia gas.
